(19) United States
(12) Patent Application Publication
(10) Pub. No.: US 2026/0344136 A1
(43) Pub. Date: Oct. 29, 2026

(54) PACKAGE STRUCTURE

(71) Applicant: Ennostar Corporation, Hsinchu City (TW)

(72) Inventors: Fu-Hsin CHEN, Hsinchu City (TW); Chun-Min LIN, Hsinchu City (TW); Shiou-Yi KUO, Hsinchu City (TW)

(21) Appl. No.: 19/660,868

(22) Filed: Apr. 28, 2026

(30) Foreign Application Priority Data
Apr. 28, 2025 (TW) 114115898

(51) Int. Cl. H10H 20/857; H10H 20/01; H10H 20/851; H10H 20/856

(52) U.S. Cl. CPC H10H 20/857; H10H 20/0361; H10H 20/0363; H10H 20/0364; H10H 20/8512; H10H 20/856

(57) ABSTRACT

A package structure is provided. The package structure includes a chip, a first pad, a color conversion layer, a reflective layer, a redistribution layer and a second pad. The first pad is disposed on the chip. The color conversion layer surrounds the chip. The reflective layer is disposed on the color conversion layer, exposing the first pad. The redistribution layer is disposed on the reflective layer and the first pad. The second pad is disposed on the redistribution layer and is electrically connected to the first pad.

### CROSS REFERENCE TO RELATED APPLICATIONS

This application claims priority of Taiwan Patent Application No. 114115898, filed on Apr. 28, 2025, the entirety of which is incorporated by reference herein.

### TECHNICAL FIELD

The present disclosure relates to a package structure, and in particular, it relates to a package structure with a reflective layer on both sides of a chip.

### BACKGROUND

### Description of the Related Art

Current packaging technology faces many problems. For example, in the traditional chip-size package (CSP) architecture, in addition to the bottom light leakage that causes a decrease in luminous efficiency, the continuous shrinking of chip size also leads to poor wire-bonding yield. In the NCSP architecture, there is a problem with secondary melting. Moreover, the BT substrate is expensive, and its component size is thicker than that of traditional CSP.

Therefore, finding a way to design a package structure that can not only avoid secondary melting during chip bonding and solve the problem of poor wire-bonding precision, but also improve the luminous efficiency at the same time is desirable.

### SUMMARY

In some embodiments, a package structure is provided. The package structure includes a chip, a first pad, a color conversion layer, a reflective layer, a redistribution layer and a second pad. The first pad is disposed on the chip. The color conversion layer surrounds the chip. The reflective layer is disposed on the color conversion layer, exposing the first pad. The redistribution layer is disposed on the reflective layer and the first pad. The second pad is disposed on the redistribution layer and is electrically connected to the first pad.

The package structure of the present disclosure can be applied in various electronic devices. In order to make the features and advantages of the present disclosure more readily be understood, various embodiments are given in the subsequent description in conjunction with the accompanying drawings.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion.

FIG. 1A illustrates a cross-sectional view of a package structure according to some embodiments of the present disclosure;

FIG. 1B illustrates a cross-sectional view of a package structure according to some embodiments of the present disclosure;

FIG. 2 illustrates a cross-sectional view of a package structure according to some embodiments of the present disclosure;

FIG. 3 illustrates a cross-sectional view of a package structure according to some embodiments of the present disclosure;

FIGS. 4A-4N illustrate cross-sectional views of a method for fabricating a package structure according to some embodiments of the present disclosure; and

FIGS. 5A-5N illustrate cross-sectional views of a method for fabricating a package structure according to some embodiments of the present disclosure.

### DETAILED DESCRIPTION

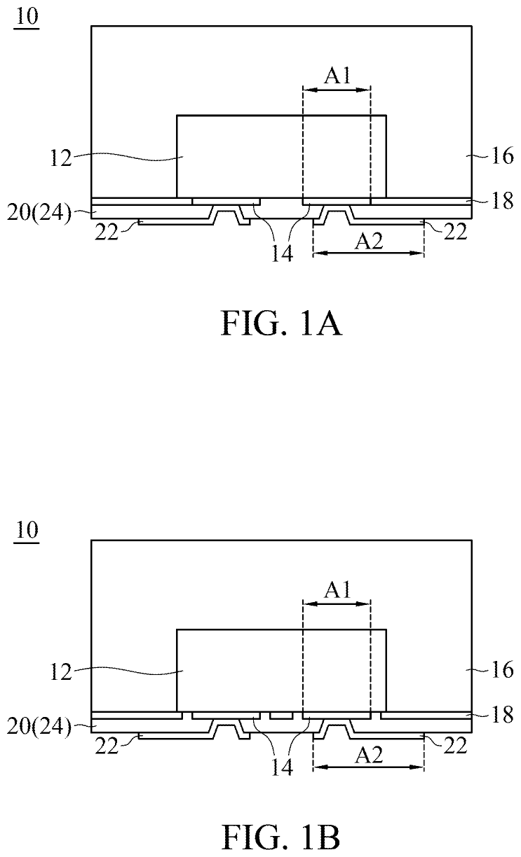

Referring to FIG. 1A, according to some embodiments of the present disclosure, a package structure 10 is provided. FIG. 1A illustrates a cross-sectional view of the package structure 10.

As shown in FIG. 1A, the package structure 10 includes a chip 12, a first pad 14, a color conversion layer 16, a reflective layer 18, a redistribution layer (RDL) 20, and a second pad 22. The first pad 14 is disposed on the chip 12. The color conversion layer 16 surrounds the chip 12. The reflective layer 18 is disposed on the color conversion layer 16, exposing the first pad 14. The redistribution layer 20 is disposed on the reflective layer 18 and the first pad 14. The second pad 22 is disposed on the redistribution layer 20 and electrically connected to the first pad 14.

In some embodiments, the chip 12 is disposed in the package structure 10 by, for example, a flip-chip manner. In some embodiments, the package structure 10 may include a single chip 12. In some embodiments, the package structure 10 may include a plurality of chips 12 arranged in a matrix, for example. In some embodiments, the chip 12 may include a light-emitting diode (LED), such as a green LED chip, a red LED chip, or a blue LED chip, but the present disclosure is not limited thereto. For example, a green LED chip can emit green (G) visible light with a wavelength of approximately between 510 nm and 570 nm, a red LED chip can emit red (R) visible light with a wavelength of approximately 610 nm to 750 nm, and a blue LED chip can emit blue (B) visible light with a wavelength of approximately between 440 nm and 470 nm. In some embodiments, the material of the LED chip may include an inorganic semiconductor material, such as a III-V compound, a II-VI compound, or other suitable semiconductor materials, but the present disclosure is not limited thereto.

In some embodiments, the chip 12 may include, for example, single-side luminescence. In some embodiments, the chip 12 may include, for example, multi-side luminescence, such as four-side luminescence or five-side luminescence, but the present disclosure is not limited thereto.

In some embodiments, the first pad 14 may include a conductive material, such as a metal material such as chromium, aluminum, nickel, gold, platinum, tin, copper, or alloys thereof, or other suitable metal materials, but the present disclosure is not limited thereto. It is worth mentioning that the aforementioned materials and combinations thereof are merely examples, and the present disclosure may adopt any materials and combinations thereof known to those skilled in the art to form the first pad 14, and is not limited to the aforementioned specific embodiments.

In some embodiments, the color conversion layer 16 may include phosphors, quantum dots (QDs), another suitable material, or a combination thereof to convert the single-color light emitted by the LED chip into light of a specific color. Taking the package structure 10 emitting white visible light as an example, the chip 12 may include a blue LED chip, and the color conversion layer 16 may include yellow phosphor. In this case, a portion of the blue visible light emitted by the blue LED chip can be absorbed by the yellow phosphor and converted into yellow visible light. In this way, the yellow visible light and the blue visible light can be mixed to emit white visible light.

In some embodiments, the chip 12 may include a blue LED chip, and the color conversion layer 16 may include red phosphor and green phosphor. In this case, a portion of the blue visible light emitted by the blue LED chip can be absorbed by the red phosphor and the green phosphor, and thus converted into red visible light and green visible light. In this way, the red visible light, the green visible light, and the blue visible light can be mixed to emit white visible light.

In some embodiments, the reflective layer 18 may be a single reflective layer. In some embodiments, the reflective layer 18 may include ink, silicone resin doped with titanium dioxide (TiO2), or other suitable reflective materials, but the present disclosure is not limited thereto. It is worth mentioning that the aforementioned materials are merely examples, and the present disclosure may adopt any material known to those skilled in the art to form the reflective layer 18, and is not limited to the aforementioned specific embodiments.

In some embodiments, the light reflectivity of the reflective layer 18 may be between 80% and 99%, but the present disclosure is not limited thereto. For example, the light reflectivity of the reflective layer 18 may be 95%, 96%, 97%, 98%, 99%, or any value or range therebetween.

In some embodiments, the redistribution layer (RDL) 20 may be composed of a plurality of dielectric layers 24 and a plurality of metal layers (not shown) stacked on one another.

In some embodiments, the dielectric layer 24 constituting the redistribution layer (RDL) 20 may include polycyclooctene (PCO), polybenzoxazole (PBO), photosensitive polyimide (PSPI), polysiloxane, or other suitable polymer materials, but the present disclosure is not limited thereto.

In some embodiments, the metal layer (not shown) constituting the redistribution layer (RDL) 20 may include metal materials such as chromium, aluminum, nickel, gold, platinum, tin, copper, or alloys thereof, or other suitable metal materials, but the present disclosure is not limited thereto.

In some embodiments, the redistribution layer (RDL) 20 may be disposed on a portion of the reflective layer 18 and the first pad 14 (not shown).

In some embodiments, the second pad 22 may include a conductive material, such as a metal material such as chromium, aluminum, nickel, gold, platinum, tin, copper, or alloys thereof, or other suitable metal materials, but the present disclosure is not limited thereto.

In some embodiments, the metal layer (not shown) of the redistribution layer (RDL) 20 electrically connects the first pad 14 and the second pad 22.

In some embodiments, the first pad 14 has a surface area A1, and the second pad 22 has a surface area A2. The surface area A2 of the second pad 22 is greater than the surface area A1 of the first pad 14.

In some embodiments, the package structure 10 may be, for example, a chip-scale package (CSP). In some embodiments, the package structure 10 may include a chip-scale package (CSP) having a light-emitting angle between about 120 degrees and about 140 degrees.

Referring to FIG. 1B, according to some embodiments of the present disclosure, a package structure 10 is provided. FIG. 1B illustrates a cross-sectional view of the package structure 10.

The difference between the embodiment of the package structure 10 shown in FIG. 1B and the embodiment of the package structure 10 shown in FIG. 1A mainly lies in the different configuration of the reflective layer 18 in the package structure, which is further described below. In FIG. 1B, other parts similar to those disclosed in FIG. 1A, such as component structure, size, and constituent materials, are not repeated here.

As shown in FIG. 1B, in some embodiments, the reflective layer 18 is not only disposed on the color conversion layer 16 to expose the first pad 14, but is also disposed between the first pads 14.

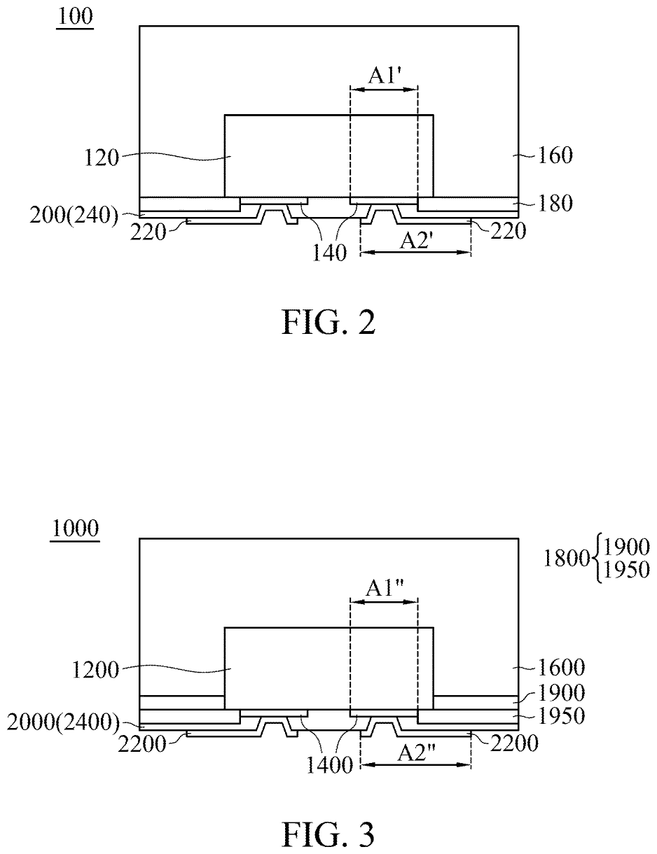

Referring to FIG. 2, according to some embodiments of the present disclosure, a package structure 100 is provided. FIG. 2 illustrates a cross-sectional view of the package structure 100.

As shown in FIG. 2, the package structure 100 includes a chip 120, a first pad 140, a color conversion layer 160, a reflective layer 180, a redistribution layer (RDL) 200, and a second pad 220. The first pad 140 is disposed on the chip 120. The color conversion layer 160 surrounds the chip 120. The reflective layer 180 is disposed on the color conversion layer 160, exposing the first pad 140. The redistribution layer 200 is disposed on the reflective layer 180 and the first pad 140. The second pad 220 is disposed on the redistribution layer 200 and electrically connected to the first pad 140. In some embodiments, the redistribution layer 200 may be composed of a plurality of dielectric layers 240 and a plurality of metal layers (not shown) stacked on one another.

In some embodiments, the first pad 140 has a surface area A1′, and the second pad 220 has a surface area A2′. The surface area A2′ of the second pad 220 is greater than the surface area A1′ of the first pad 140.

The difference between the embodiment of the package structure 100 shown in FIG. 2 and the embodiment of the package structure 10 shown in FIG. 1 mainly lies in the different constituent materials of the reflective layer 180 of the package structure 100 and the reflective layer 18 of the package structure 10, which is further described below. In FIG. 2, other parts similar to those disclosed in FIG. 1, such as component structure, size, and constituent materials, are not described again.

As shown in FIG. 2, in some embodiments, the reflective layer 180 may be a single reflective layer. In some embodiments, the reflective layer 180 may include gold, silver, titanium, copper, aluminum, or an alloy or combination thereof, or other suitable metal reflective materials, but the present disclosure is not limited thereto.

Referring to FIG. 3, according to some embodiments of the present disclosure, a package structure 1000 is provided. FIG. 3 illustrates a cross-sectional view of the package structure 1000.

As shown in FIG. 3, the package structure 1000 includes a chip 1200, a first pad 1400, a color conversion layer 1600, a reflective layer 1800, a redistribution layer (RDL) 2000, and a second pad 2200. The first pad 1400 is disposed on the chip 1200. The color conversion layer 1600 surrounds the chip 1200. The reflective layer 1800 is disposed on the color conversion layer 1600, exposing the first pad 1400. The redistribution layer 2000 is disposed on the reflective layer 1800 and the first pad 1400. The second pad 2200 is disposed on the redistribution layer 2000 and electrically connected to the first pad 1400. In some embodiments, the redistribution layer 2000 may be composed of a plurality of dielectric layers 2400 and a plurality of metal layers (not shown) stacked on one another. In some embodiments, the first pad 1400 has a surface area A1 “, and the second pad 2200 has a surface area A2”. The surface area A2″ of the second pad 2200 is greater than the surface area A1″ of the first pad 1400.

The difference between the embodiment of the package structure 1000 shown in FIG. 3 and the embodiment of the package structure 10 shown in FIG. 1 mainly lies in the different number of layers and constituent materials between the reflective layer 1800 of the package structure 1000 and the reflective layer 18 of the package structure 10, which is further described below. In FIG. 3, other parts similar to those disclosed in FIG. 1, such as component structure, size, and constituent materials, are not described again.

As shown in FIG. 3, in some embodiments, the reflective layer 1800 may include a first reflective layer 1900 and a second reflective layer 1950. The first reflective layer 1900 is disposed on the color conversion layer 1600. The second reflective layer 1950 is disposed on the first reflective layer 1900. In some embodiments, the first reflective layer 1900 may include ink, silicone resin doped with titanium dioxide (TiO2), or other suitable reflective materials, but the present disclosure is not limited thereto. It is worth mentioning that the aforementioned materials are merely examples, and the present disclosure may adopt any material known to those skilled in the art to form the first reflective layer 1900, and is not limited to the aforementioned specific embodiments.

In some embodiments, the second reflective layer 1950 may include gold, silver, titanium, copper, aluminum, or an alloy or combination thereof, or other suitable metal reflective materials, but the present disclosure is not limited thereto.

In some embodiments, the material compositions of the first reflective layer 1900 and the second reflective layer 1950 are interchangeable. For example, the first reflective layer 1900 may include gold, silver, titanium, copper, aluminum, or an alloy or combination thereof, or other suitable metal reflective materials, but the present disclosure is not limited thereto. The second reflective layer 1950 may include ink, silicone resin doped with titanium dioxide (TiO2), or other suitable reflective materials, but the present disclosure is not limited thereto.

In some embodiments, a plurality of package structures (10, 100, or 1000) as shown in FIGS. 1A-3 may be further disposed on a substrate (not shown) to form a backlight module (not shown).

In some embodiments, a plurality of package structures (10, 100, or 1000) as shown in FIGS. 1A-3 are disposed on a substrate in a matrix manner and by metal welding.

In some embodiments, the material of the aforementioned substrate may include: Group IV elements or Group IV compounds, such as silicon (Si), diamond (C), or silicon carbide (SiC); Group III-V compounds, such as gallium nitride (GaN), aluminum gallium nitride (AlGaN), aluminum nitride (AlN), gallium phosphide (GaP), gallium arsenide (GaAs), aluminum gallium arsenide (AlGaAs), another suitable material, or a combination thereof, but the present disclosure is not limited thereto.

In some embodiments, the aforementioned substrate may include a flexible substrate, a soft substrate, a rigid substrate, or a combination thereof, but the present disclosure is not limited thereto.

In some embodiments, the material of the aforementioned substrate may include glass, quartz, sapphire, ceramic, or other suitable materials or a combination thereof, but the present disclosure is not limited thereto. For example, the aforementioned substrate may be a sapphire substrate. In some embodiments, the material of the aforementioned substrate may include polyimide (PI), polycarbonate (PC), polyethylene terephthalate (PET), polypropylene (PP), polysiloxane, another suitable material, or a combination thereof, but the present disclosure is not limited thereto.

In some embodiments, the aforementioned substrate may include a light-transmitting substrate, a semi-light-transmitting substrate, or an opaque substrate, but the present disclosure is not limited thereto.

In some embodiments, a plurality of package structures (10, 100, or 1000) as shown in FIGS. 1A-3 may emit visible light of the same color, but the present disclosure is not limited thereto. For example, the visible light may be white light, blue light, red light, green light, yellow light, or other suitable visible light or a combination thereof, but the present disclosure is not limited thereto.

In some embodiments, some of the package structures (10, 100, or 1000) shown in FIGS. 1A-3 may emit a first visible light, while others may emit a second visible light. The first visible light may be different from the second visible light.

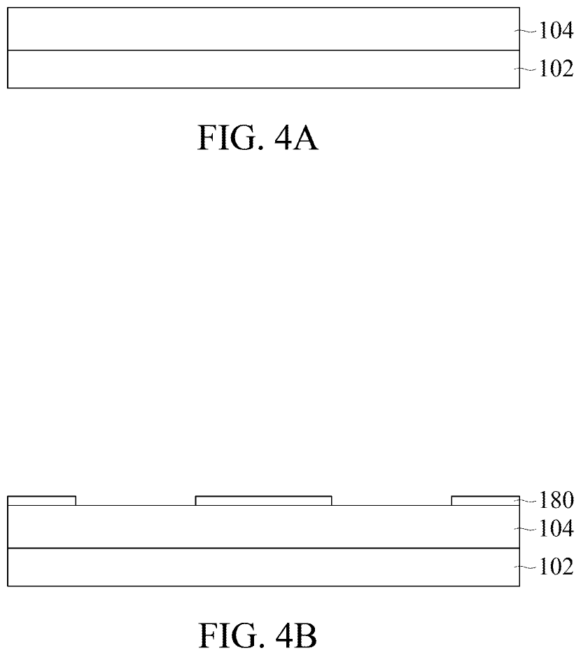

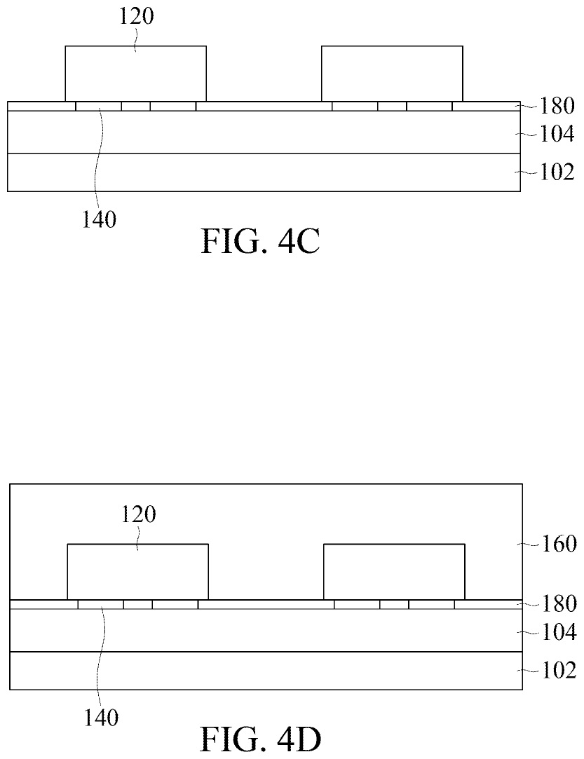

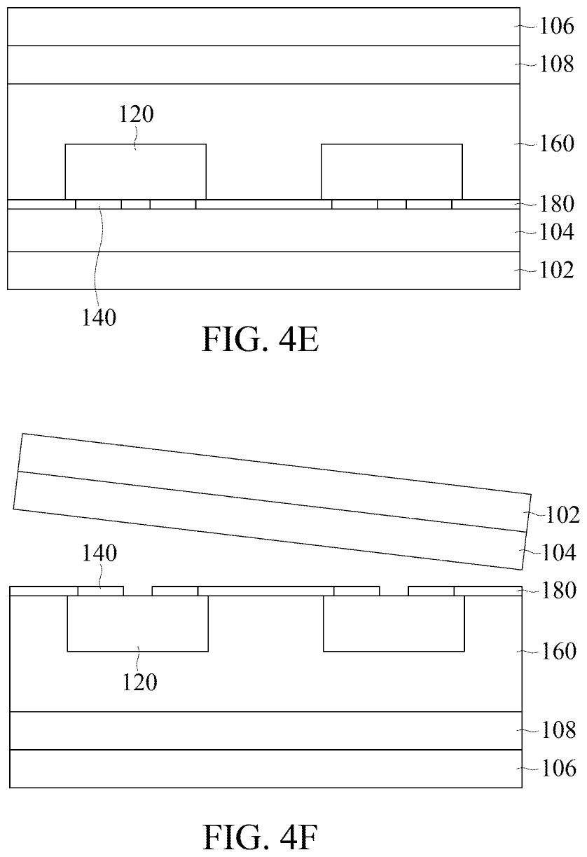

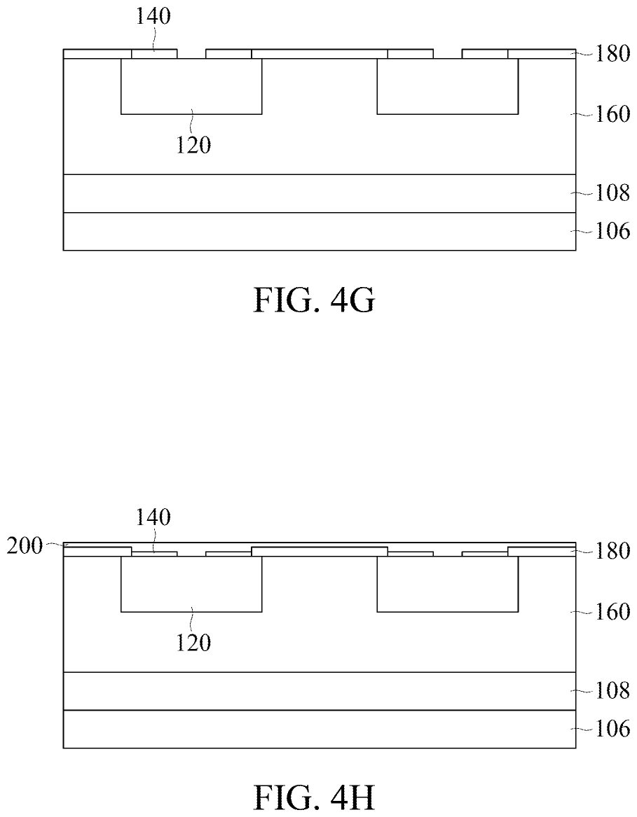

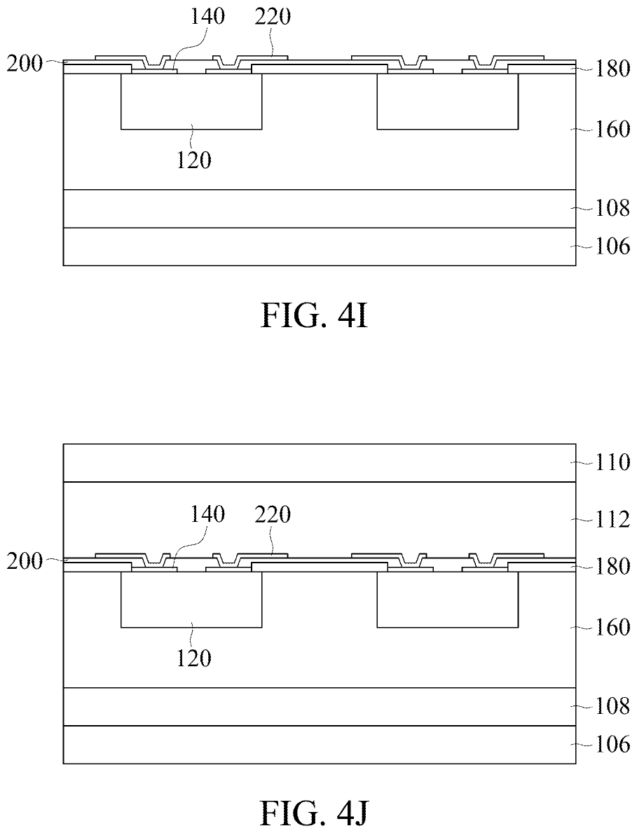

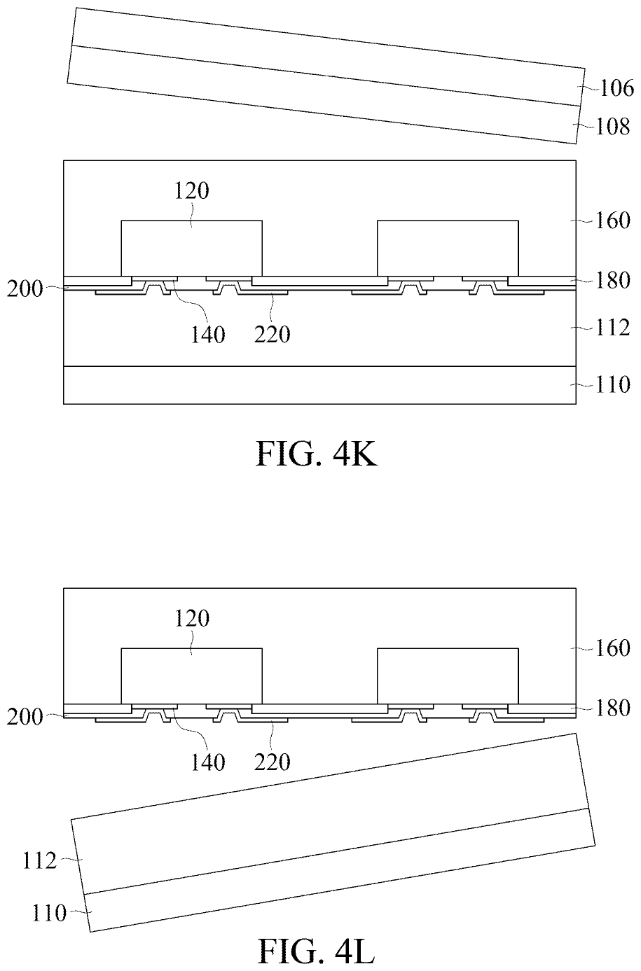

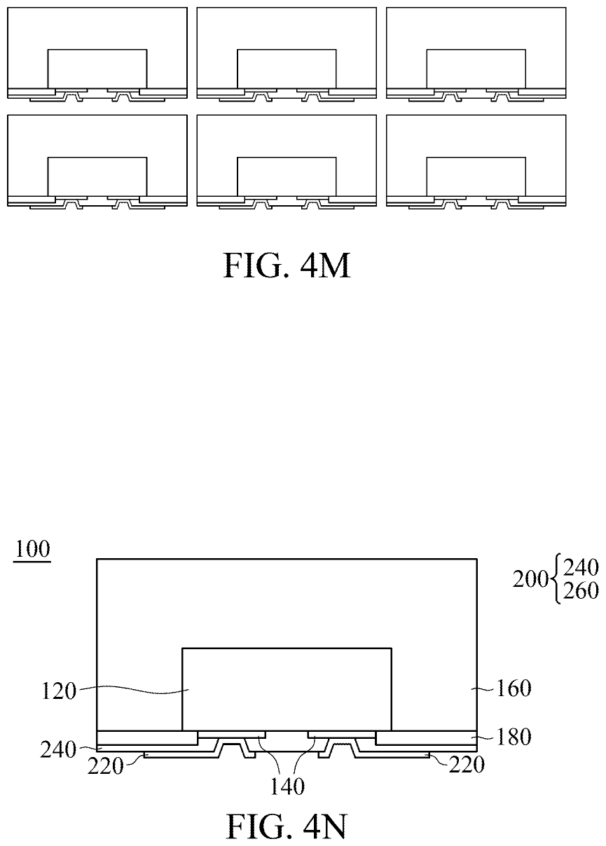

Referring to FIGS. 4A-4N, according to some embodiments of the present disclosure, a method for fabricating the package structure 100 as shown in FIG. 2 is provided. FIGS. 4A-4N illustrate cross-sectional views of the method for fabricating the package structure.

As shown in FIG. 4A, a first carrier 102 is provided, on which a first laser dissociation layer 104 is disposed.

As shown in FIG. 4B, a patterned reflective layer 180 is formed on the first carrier 102. In some embodiments, the patterned reflective layer 180 may include gold, silver, titanium, copper, aluminum, or an alloy or combination thereof, or other suitable metal reflective materials, but the present disclosure is not limited thereto. It is worth mentioning that the aforementioned materials and combinations thereof are merely examples, and the present disclosure may adopt any materials and combinations thereof known to those skilled in the art to form the patterned reflective layer 180, and is not limited to the aforementioned specific embodiments.

As shown in FIG. 4C, a chip 120 is disposed on the first carrier 102. The chip 120 is disposed on the first carrier 102 through a first pad 140, and the patterned reflective layer 180 is located on the both sides of the chip 120.

In some embodiments, the chip 120 is disposed on the first carrier 102 by, for example, a flip-chip manner.

In some embodiments, the chip 120 may include a light-emitting diode (LED), such as a green LED chip, a red LED chip, or a blue LED chip, but the present disclosure is not limited thereto.

In some embodiments, the material of the chip 120 may include an inorganic semiconductor material, such as a III-V compound, a II-VI compound, or other suitable semiconductor materials, but the present disclosure is not limited thereto.

In some embodiments, the chip 120 may include, for example, single-side luminescence. In some embodiments, the chip 120 may include, for example, multi-side luminescence, such as four-side luminescence or five-side luminescence, but the present disclosure is not limited thereto. In some embodiments, the first pad 140 may include a conductive material, such as a metal material such as chromium, aluminum, nickel, gold, platinum, tin, copper, or alloys thereof, or other suitable metal materials, but the present disclosure is not limited thereto.

As shown in FIG. 4D, a color conversion layer 160 is formed to cover the chip 120 and the patterned reflective layer 180. The color conversion layer 160 may include phosphors, quantum dots (QDs), another suitable material, or a combination thereof to convert the single-color light emitted by the chip 120 into light of a specific color.

As shown in FIG. 4E, a second carrier 106 is provided, on which a second laser dissociation layer 108 is disposed. Next, the second carrier 106 is disposed on the color conversion layer 160. The second carrier 106 is opposite to the first carrier 102.

As shown in FIG. 4F, the first carrier 102 and the first laser dissociation layer 104 are removed to expose the patterned reflective layer 180 and the first pad 140.

As shown in FIG. 4G, a surface cleaning process is performed, such as using inductively coupled plasma (ICP) to perform the surface cleaning process.

As shown in FIG. 4H, a redistribution layer (RDL) 200 is formed on the patterned reflective layer 180 and the first pad 140. In some embodiments, the redistribution layer 200 may be composed of a plurality of dielectric layers and a plurality of metal layers stacked on one another. In some embodiments, the dielectric layer constituting the redistribution layer 200 may include polycyclooctene (PCO), polybenzoxazole (PBO), photosensitive polyimide (PSPI), polysiloxane, or other suitable polymer materials, but the present disclosure is not limited thereto.

In addition, in some embodiments, the metal layer constituting the redistribution layer 200 may include metal materials such as chromium, aluminum, nickel, gold, platinum, tin, copper, or alloys thereof, or other suitable metal materials, but the present disclosure is not limited thereto.

As shown in FIG. 4I, a second pad 220 extends from the redistribution layer 200. The second pad 220 is electrically connected to the first pad 140. In some embodiments, the second pad 220 may include a conductive material, such as a metal material such as chromium, aluminum, nickel, gold, platinum, tin, copper, or alloys thereof, or other suitable metal materials, but the present disclosure is not limited thereto.

In some embodiments, the surface area of the second pad 220 is greater than the surface area of the first pad 140.

As shown in FIG. 4J, a third carrier 110 is provided, on which a third laser dissociation layer 112 is disposed. Next, the third carrier 110 is disposed on the redistribution layer 200. The third carrier 110 is opposite to the second carrier 106.

As shown in FIG. 4K, the second carrier 106 and the second laser dissociation layer 108 are removed to expose the color conversion layer 160.

As shown in FIG. 4L, the third carrier 110 and the third laser dissociation layer 112 are removed to expose the redistribution layer 200 and the second pad 220.

As shown in FIG. 4M, a cutting process is performed to complete the production of the package structure 100 shown in FIG. 2, as shown in FIG. 4N.

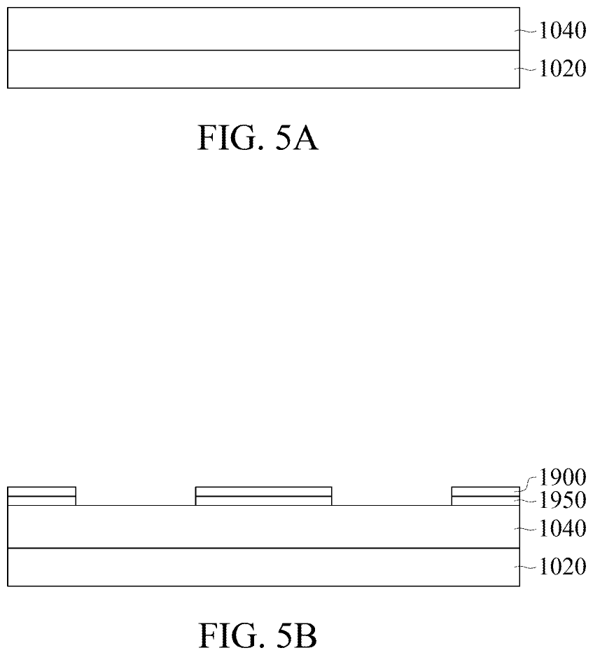

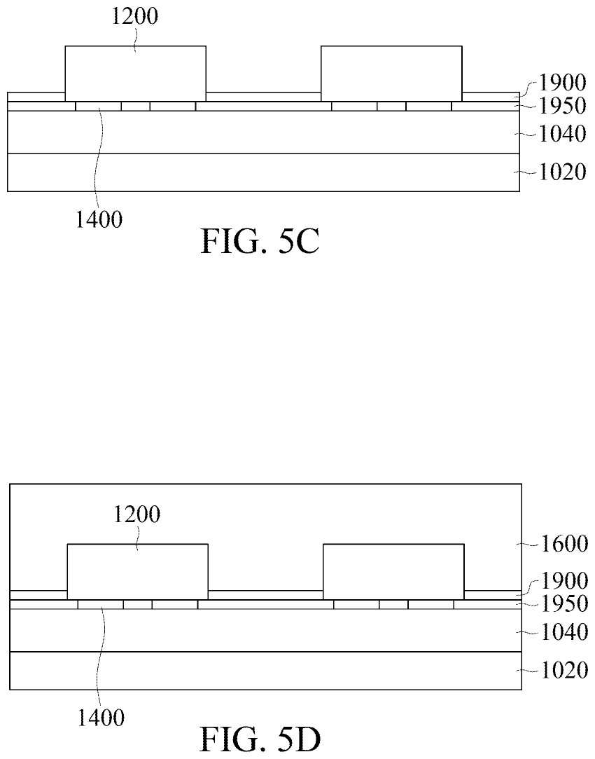

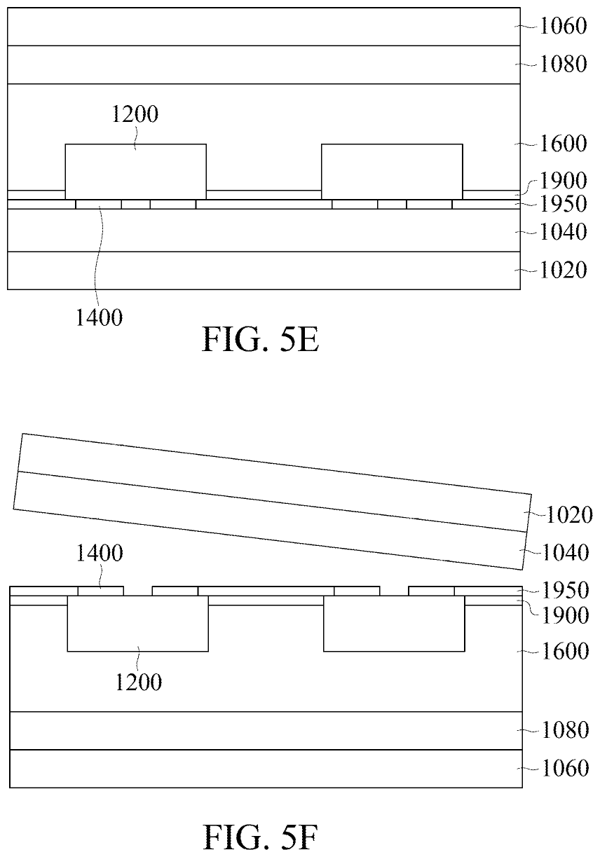

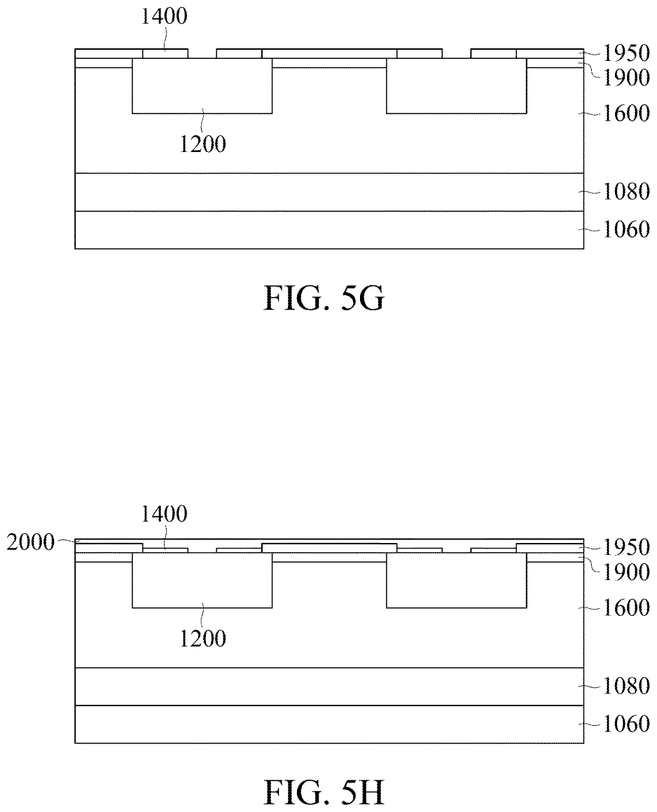

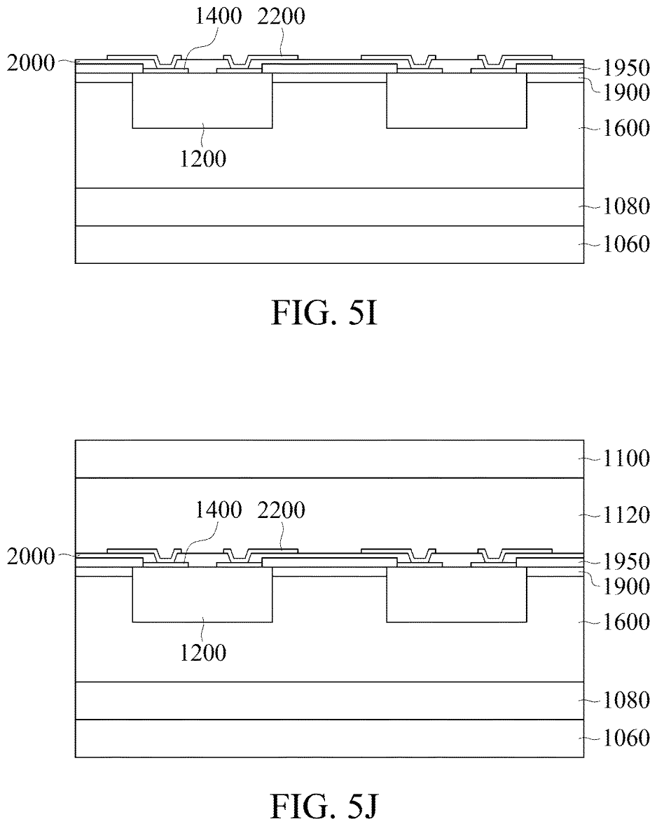

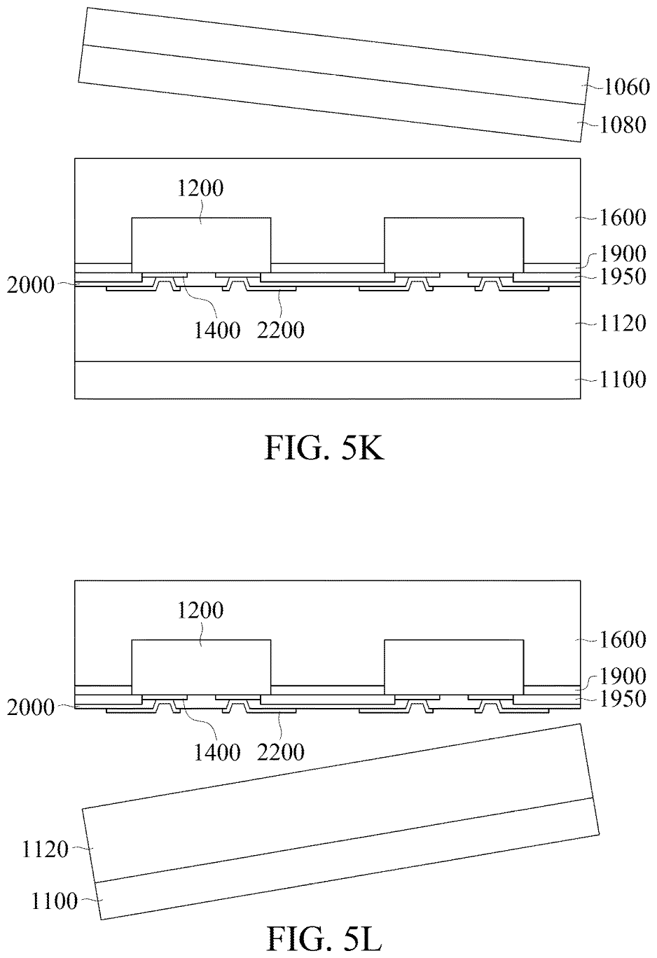

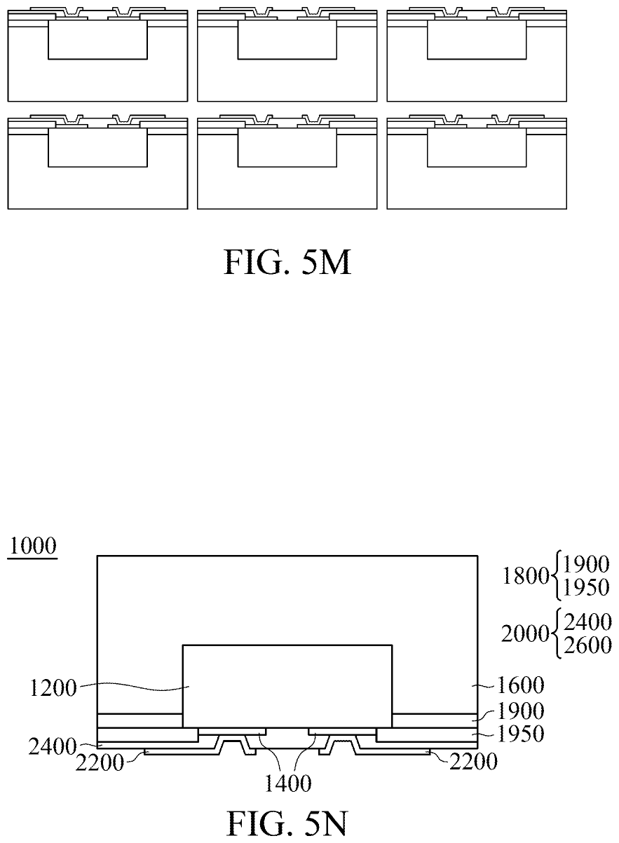

Referring to FIGS. 5A-5N, according to some embodiments of the present disclosure, a method for fabricating the package structure 1000 is provided. FIGS. 5A-5N illustrate cross-sectional views of the method for fabricating the package structure.

The difference between the embodiment of the package structure 1000 shown in FIGS. 5A-5N and the embodiment of the package structure 100 shown in FIGS. 4A-4N mainly lies in the different number of layers and constituent materials between the reflective layer 1800 of the package structure 1000 and the reflective layer 180 of the package structure 100, which is further explained below. In FIGS. 5A-5N, other parts similar to those disclosed in FIGS. 4A-4N, such as component structure, size, and constituent materials, are not repeated here.

As shown in FIG. 5A, a first carrier 1020 is provided, on which a first laser dissociation layer 1040 is disposed.

As shown in FIG. 5B, a second patterned reflective layer 1950 is formed on the first carrier 1020, and a first patterned reflective layer 1900 is formed on the second patterned reflective layer 1950.

In some embodiments, the first patterned reflective layer 1900 may include ink, silicone resin doped with titanium dioxide (TiO2), or other suitable reflective materials, but the present disclosure is not limited thereto.

In some embodiments, the second patterned reflective layer 1950 may include gold, silver, titanium, copper, aluminum, or an alloy or combination thereof, or other suitable metal reflective materials, but the present disclosure is not limited thereto.

In some embodiments, the material compositions of the first patterned reflective layer 1900 and the second patterned reflective layer 1950 are interchangeable. For example, the first patterned reflective layer 1900 may include gold, silver, titanium, copper, aluminum, or an alloy or combination thereof, or other suitable metal reflective materials, but the present disclosure is not limited thereto. The second patterned reflective layer 1950 may include ink, silicone resin doped with titanium dioxide (TiO2), or other suitable reflective materials, but the present disclosure is not limited thereto.

As shown in FIG. 5C, a chip 1200 is disposed on the first carrier 1020. The chip 1200 is disposed on the first carrier 1020 through a first pad 1400. The first patterned reflective layer 1900 and the second patterned reflective layer 1950 are located on the both sides of the chip 1200.

As shown in FIG. 5D, a color conversion layer 1600 is further formed to cover the chip 1200, the first patterned reflective layer 1900, and the second patterned reflective layer 1950.

As shown in FIG. 5E, a second carrier 1060 is provided, on which a second laser dissociation layer 1080 is disposed. Next, the second carrier 1060 is disposed on the color conversion layer 1600. The second carrier 1060 is opposite to the first carrier 1020.

As shown in FIG. 5F, the first carrier 1020 and the first laser dissociation layer 1040 are removed to expose the first patterned reflective layer 1900, the second patterned reflective layer 1950, and the first pad 1400.

As shown in FIG. 5G, a surface cleaning process is performed, for example, using inductively coupled plasma (ICP) to perform the surface cleaning process.

As shown in FIG. 5H, a redistribution layer 2000 is formed on the first patterned reflective layer 1900, the second patterned reflective layer 1950, and the first pad 1400.

As shown in FIG. 5I, the second pad 2200 extends from the redistribution layer 2000. The second pad 2200 is electrically connected to the first pad 1400.

As shown in FIG. 5J, a third carrier 1100 is provided, on which a third laser dissociation layer 1120 is disposed. Next, the third carrier 1100 is disposed on the redistribution layer 2000. The third carrier 1100 is opposite to the second carrier 1060.

As shown in FIG. 5K, the second carrier 1060 and the second laser dissociation layer 1080 are removed to expose the color conversion layer 1600.

As shown in FIG. 5L, the third carrier 1100 and the third laser dissociation layer 1120 are removed to expose the redistribution layer 2000 and the second pad 2200.

As shown in FIG. 5M, a cutting process is performed to complete the production of the package structure 1000 shown in FIG. 3, as shown in FIG. 5N.

### Example 1

### Luminous Efficiency Test (I) on the Package Structures

In this example, the conventional package structure I and the disclosed package structure II were used to conduct a test and comparison on the luminous efficiency. The test results are listed in Table 1 below.

TABLE 1

| | Package structure I | Package structure II |
|---|---|---|
| Structures | (no reflective layer) | (shown in FIG. 1) |
| Chromaticity | 0.2785, 0.2801 | 0.2825, 02877 |
| coordinate | | |
| (CIEx,y) | | |
| Luminous | 10.44 | 10.96 |
| flux (lm) | | |
| Luminous | 124.90 | 131.23 |
| efficiency | | |
| (lm/W) | | |
| Efficiency | 0 | +4.98 |
| gain (%) | | |

It can be seen from the test results in Table 1 that, compared with the conventional package structure I without a reflective layer, the luminous efficiency of the disclosed package structure II with the reflective layer composed of ink or silicone resin doped with titanium dioxide (TiO2) disposed on the both sides of the chip can be improved by at least 4.98%.

### Example 2

### Luminous Efficiency Test (II) on the Package Structures

In this example, the conventional package structure I and the disclosed package structure III were used to conduct a test and comparison on the luminous efficiency. The test results are listed in Table 2 below.

TABLE 2

| | Package structure I | Package structure III |
|---|---|---|
| Structures | (no reflective layer) | (shown in FIG. 2) |
| Chromaticity | 0.2898, 0.2879 | 0.2898, 02879 |
| coordinate | | |
| (CIEx,y) | | |
| Luminous | 3.9 | 4.11 |
| flux (lm) | | |
| Luminous | 140 | 153.27 |
| efficiency | | |
| (lm/W) | | |
| Efficiency | 0 | +9.3 |
| gain (%) | | |

It can be seen from the test results in Table 2 that, compared with the conventional package structure I without a reflective layer, the luminous efficiency of the disclosed package structure III with the reflective layer composed of gold, silver, titanium, copper, aluminum, or an alloy or combination thereof disposed on the both sides of the chip can be improved by at least 9.3%.

In summary, the present disclosure provides a package structure, which is provided with a reflective layer (ex. single layer or double layer) composed of, for example, ink, silicone resin doped with titanium dioxide (TiO2), or metal material, on both sides of a chip, and a redistribution layer (RDL) that enlarges the surface area of a first pad to a second pad, and is combined with a technology of setting the package structure on a substrate by metal welding. This not only avoids secondary melting when bonding the chips, but also solves the problem of poor wire-bonding accuracy, and can simultaneously improve the luminous efficiency.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and operations described in the specification. As one of ordinary skill in the art will readily appreciate from the disclosure of the present disclosure, processes, machines, manufacture, compositions of matter, means, methods, or operations, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or operations.

What is claimed is:

1. A package structure, comprising:
a chip;
a first pad disposed on the chip;
a color conversion layer surrounding the chip;
a reflective layer disposed on the color conversion layer, and exposing the first pad;
a redistribution layer (RDL) disposed on the reflective layer and the first pad; and
a second pad disposed on the redistribution layer and electrically connected to the first pad.

2. The package structure as claimed in claim 1, wherein the color conversion layer comprises phosphors or quantum dots (QDs).

3. The package structure as claimed in claim 1, wherein, in a cross sectional view, the reflective layer has a portion not overlapping the second pad in a vertical direction.

4. The package structure as claimed in claim 1, wherein the reflective layer is a first reflective layer which comprises ink or silicone resin doped with titanium dioxide (TiO2).

5. The package structure as claimed in claim 1, wherein the reflective layer comprises gold, silver, titanium, copper, aluminum, an alloy thereof, or a combination thereof.

6. The package structure as claimed in claim 1, wherein the reflective layer comprises a first reflective layer and a second reflective layer, the first reflective layer is disposed on the color conversion layer, and the second reflective layer is disposed on the first reflective layer.

7. The package structure as claimed in claim 6, wherein the first reflective layer comprises ink or silicone resin doped with titanium dioxide (TiO2), and the second reflective layer comprises gold, silver, titanium, copper, aluminum, an alloy thereof, or a combination thereof.

8. The package structure as claimed in claim 1, wherein the redistribution layer comprises a plurality of dielectric layers and a plurality of metal layers which are stacked on one another.

9. The package structure as claimed in claim 8, wherein the plurality of metal layers electrically connect the first pad to the second pad.

10. The package structure as claimed in claim 1, wherein the first pad and the second pad comprise a conductive material.

11. The package structure as claimed in claim 1, wherein the second pad has a surface area greater than that of the first pad.

12. The package structure as claimed in claim 1, wherein the package structure is a chip-scale package (CSP).

13. A method of fabricating a package structure, comprising:
providing a first carrier;
disposing a first laser dissociation layer on the first carrier;
forming a patterned reflective layer on the first laser dissociation layer;
disposing a chip on the first carrier through a first pad, wherein the patterned reflective layer is located on both sides of the chip;
forming a color conversion layer to cover the chip and the patterned reflective layer;
disposing a second laser dissociation layer on the color conversion layer;
disposing a second carrier on the second laser dissociation layer;
removing the first carrier and the first laser dissociation layer to expose the patterned reflective layer and the first pad;
forming a redistribution layer on the patterned reflective layer and the first pad;
forming a second pad which is extended from the redistribution layer and electrically connected to the first pad;
disposing a third laser dissociation layer on the redistribution layer and the redistribution layer;
disposing a third carrier on the third laser dissociation layer;
removing the second carrier and the second laser dissociation layer; and
removing the third carrier and the third laser dissociation layer to expose the redistribution layer and the second pad.

14. The method of fabricating a package structure as claimed in claim 13, wherein the patterned reflective layer comprises ink or silicone resin doped with titanium dioxide (TiO2).

15. The method of fabricating a package structure as claimed in claim 13, wherein the patterned reflective layer comprises gold, silver, titanium, copper, aluminum, an alloy thereof, or a combination thereof.

16. The method for fabricating a package structure as claimed in claim 13, wherein the step of forming the patterned reflective layer on the first carrier comprises forming a first patterned reflective layer on the first carrier, and forming a second patterned reflective layer on the first patterned reflective layer.

17. The method of fabricating a package structure as claimed in claim 16, wherein the first patterned reflective layer comprises gold, silver, titanium, copper, aluminum, an alloy thereof or a combination thereof, and the second patterned reflective layer comprises ink or silicone resin doped with titanium dioxide (TiO2).

18. The method of fabricating a package structure as claimed in claim 13, wherein the first pad and the second pad comprise a conductive material.

19. The method of fabricating a package structure as claimed in claim 13, wherein the first pad has a first surface area, the second pad has a second surface area greater than the first surface area.

20. The method of fabricating a package structure as claimed in claim 13, further comprising disposing the package structure on a substrate by metal welding.
